(19) United States
(12) Patent Application Publication
(10) Pub. No.: US 2022/0230667 A1
(43) Pub. Date: Jul. 21, 2022

(54) WORD LINE CONTROL CIRCUIT AND SEMICONDCUTOR APPARATUS INCLUDING THE SAME

(71) Applicant: SK hynix Inc., Gyeonggi-do (KR)

(72) Inventors: Chul Moon JUNG, Gyeonggi-do (KR); Duck Hwa HONG, Gyeonggi-do (KR)

(21) Appl. No.: 17/336,591

(22) Filed: Jun. 2, 2021

(30) Foreign Application Priority Data
Jan. 19, 2021 (KR) 10-2021-0007172

(51) Int. Cl. G11C 8/08

(52) U.S. Cl. CPC G11C 8/08

(57) ABSTRACT

Disclosed is a word line control circuit including a first driving unit configured to apply a first power supply voltage or a second power supply voltage to a word line according to a first word line control signal; a second driving unit configured to drop a voltage level of the word line to a first target level during a first period by using a third power supply voltage according to output of the first driving unit and a second word line control signal; and a third driving unit configured to maintain the voltage level of the word line at substantially the first target level during a second period according to a third word line control signal, and to drop the voltage level of the word line to a second target level during a third period by using a fourth power supply voltage.

### CROSS-REFERENCES TO RELATED APPLICATION

The present application claims priority under 35 U.S.C. § 119(a) to Korean application number 10-2021-0007172, filed on Jan. 19, 2021, which is incorporated herein by reference in its entirety.

### BACKGROUND

### 1. Technical Field

Various embodiments of the present invention generally relate to a semiconductor circuit, and particularly, to a word line control circuit and a semiconductor apparatus including the same.

### 2. Related Art

FIG. 1 is a diagram illustrating a word line control method in accordance with the related art.

Referring to FIG. 1, when an active command ACT is applied for an operation such as read and write of a semiconductor apparatus, a voltage VPP is applied to a word line WL in order to select a memory cell, that is, a capacitor CC, and when the capacitor CC is deselected by a precharge command PCG, the word line WL is driven with a voltage VBBW lower than the high voltage VPP. Therefore, the voltage level of the word line WL exponentially decreases from VPP to VBBW.

In such a case, precharge-active time (tRP: PCG to ACT) and row hammer characteristics are affected by a time tf required when the voltage level of the word line WL decreases from VPP to VBBW.

As tf increases, the tRP characteristics deteriorate because the time required when a gate terminal of a transistor TR for selecting the capacitor CC is maintained at a voltage higher than a threshold voltage VT becomes longer.

That is, as the time required for the voltage level of the word line WL to be maintained at VPP higher than the threshold voltage VT of the transistor TR becomes longer, the tRP characteristics deteriorate.

When the amount of charge stored in a memory cell is affected by active precharge of a word line adjacent to a word line to which a corresponding memory cell is electrically connected, data of the memory cell may deteriorate within a shorter time than a refresh interval, which may be called row hammer.

A semiconductor apparatus in accordance with the related art may have problems of deterioration in operation characteristics, that is, deterioration in row hammer characteristics as the time tf is shortened, and deterioration in tRP characteristics as the time tf is lengthened.

### SUMMARY

Various embodiments of the present disclosure are directed to providing a word line control circuit capable of substantially preventing deterioration in operation characteristics and a semiconductor apparatus including the same.

In an embodiment of the present disclosure, a word line control circuit may include: a first driving unit configured to apply a first power supply voltage or a second power supply voltage to a word line according to a first word line control signal; a second driving unit configured to drop a voltage level of the word line to a first target level during a first period by using a third power supply voltage according to output of the first driving unit and a second word line control signal; and a third driving unit configured to substantially maintain the voltage level of the word line at the first target level during a second period according to a third word line control signal, and to drop the voltage level of the word line to a second target level during a third period by using a fourth power supply voltage.

In an embodiment of the present disclosure, a semiconductor apparatus may include: a control signal generation unit configured to generate a plurality of word line control signals in response to an active signal; and a word line driving unit configured to drop a voltage level of a word line to a first target level during a first period, to substantially maintain the voltage level of the word line at the first target level during a second period, and to drop the voltage level of the word line to a second target level during a third period, according to the plurality of word line control signals.

In an embodiment of the present disclosure, a semiconductor apparatus may be configured to drop a voltage level of a word line to a first target level during a first period in response to an active signal, to substantially maintain the voltage level of the word line at the first target level during a second period, and to drop the voltage level of the word line to a second target level during a third period.

### BRIEF DESCRIPTION OF THE DRAWINGS

FIG. 1 is a diagram illustrating a word line control method in accordance with the related art.

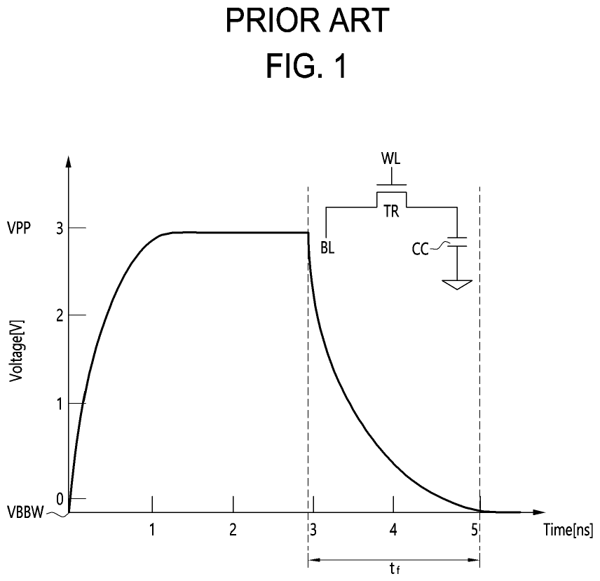

FIG. 2 is a diagram illustrating a configuration of a word line control circuit 100 in accordance with an embodiment of the present disclosure.

FIG. 3 is a diagram illustrating a configuration of a control signal generation unit 101 of FIG. 2.

FIG. 4 is a diagram illustrating a configuration of a voltage control unit 103 of FIG. 2, in accordance with an embodiment of the present disclosure.

FIG. 5 is a diagram illustrating a configuration of a word line driving unit 105 of FIG. 2, in accordance with an embodiment of the present disclosure.

FIG. 6 is a diagram illustrating an operation timing of the word line driving unit 105 of FIG. 5, in accordance with an embodiment of the present disclosure.

FIG. 7 is a diagram illustrating a word line control method in accordance with an embodiment of the present disclosure.

FIG. 8 is a diagram illustrating a configuration of a word line control circuit 200 in accordance with another embodiment of the present disclosure.

FIG. 9 is a diagram illustrating a configuration of a control signal generation unit 201 of FIG. 8, in accordance with an embodiment of the present disclosure.

FIG. 10 is a diagram illustrating a configuration of a word line driving unit 205 of FIG. 8, in accordance with an embodiment of the present disclosure.

FIG. 11 is a diagram illustrating an operation timing of the word line driving unit 205 of FIG. 10, in accordance with an embodiment of the present disclosure.

FIG. 12 is a diagram illustrating a word line control method in accordance with another embodiment of the present disclosure.

### DETAILED DESCRIPTION

Hereinafter, embodiments of the present disclosure will be described in more detail with reference to the accompanying drawings.

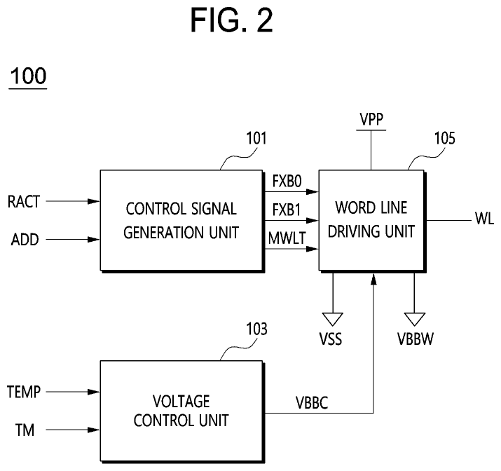

FIG. 2 is a diagram illustrating a configuration of a word line control circuit 100 in accordance with an embodiment of the present disclosure.

Referring to FIG. 2, the word line control circuit 100 in accordance with an embodiment may include a control signal generation unit 101, a voltage control unit 103, and a word line driving unit 105.

The control signal generation unit 101 may generate a plurality of control signals, that is, a plurality of word line control signals FXB0, FXB1, and MWLT according to an active signal RACT and an address signal ADD.

The active signal RACT is a signal for activating a word line WL, that is, applying a power supply voltage VPP to the word line WL.

As the active signal RACT is activated, that is, as the active signal RACT has a high level, the power supply voltage VPP may be applied to the word line WL.

The active signal RACT may have a high level according to an active command and have a low level according to a precharge command.

The address signal ADD may include a plurality of signal bits, and each of the plurality of word line control signals FXB0, FXB1, and MWLT may include a plurality of signal bits.

The word line driving unit 105 may cause a voltage level variation of the word line WL to be performed in a plurality of steps according to the plurality of word line control signals FXB0, FXB1, and MWLT and a plurality of power supply voltages VPP, VSS, VBBW, and VBBC.

The word line driving unit 105 may drop the voltage level of the word line WL to a first target level during a first period, maintain the voltage level of the word line WL substantially at the first target level during a second period, and then drop the voltage level of the word line WL to a second target level during a third period according to the plurality of word line control signals FXB0, FXB1, and MWLT and the plurality of power supply voltages VPP, VSS, VBBW, and VBBC.

The voltage control unit 103 may control the first target level according to at least one of temperature information TEMP and a test mode signal TM of a semiconductor apparatus including the word line control circuit 100.

The voltage control unit 103 may generate one power supply voltage VBBC for controlling the first target level among the plurality of power supply voltages VPP, VSS, VBBW, and VBBC according to the temperature information TEMP and the test mode signal TM.

The voltage control unit 103 may adjust the voltage level of VBBC according to the temperature information TEMP and the test mode signal TM.

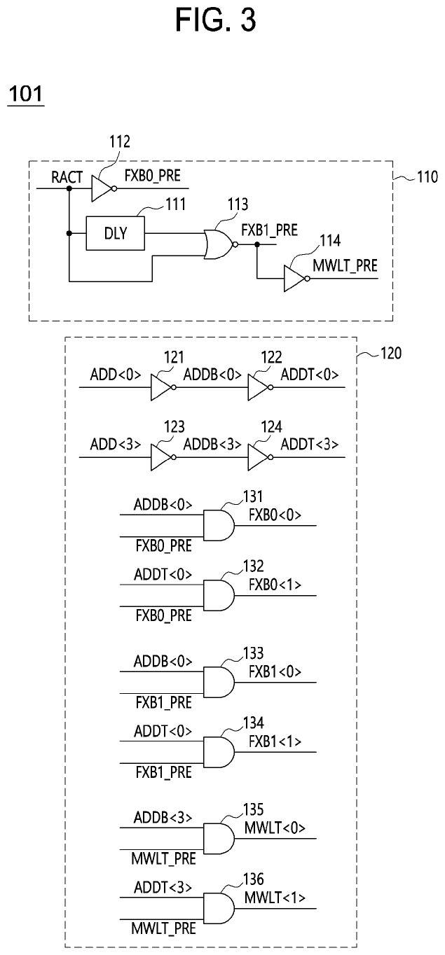

FIG. 3 is a diagram illustrating a configuration of the control signal generation unit 101 of FIG. 2, in accordance with an embodiment of the present disclosure.

FIG. 3 is only an example according to some bits of the address signal ADD, for example, bits in the order of ‘0’ and ‘3’, and the control signal generation unit 101 may have other signal configurations according to the number of bits of the address signal ADD.

Referring to FIG. 3, the control signal generation unit 101 of FIG. 2 may include a first signal generation section 110 and a second signal generation section 120. The control signal generation unit 101, the first signal generation section 110 and the second signal generation section 120 include all circuits, systems, software, firmware and devices necessary for their respective operations and functions.

The first signal generation section 110 may generate preliminary control signals FXB0_PRE, FXB1_PRE, and MWLT_PRE according to the active signal RACT.

The first signal generation section 110 may include a delay 111, a first inverter 112, a NOR gate 113, and a second inverter 114.

The delay 111 may delay the active signal RACT by a preset time and output the delayed signal.

The first inverter 112 may output a signal, which is obtained by inverting the active signal RACT, as one of the preliminary control signals FXB0_PRE, FXB1_PRE, and MWLT_PRE, for example, a first preliminary control signal FXB0_PRE.

The NOR gate 113 may output a result, which is obtained by performing a NOR operation on the output of the delay 111 and the active signal RACT, as another one of the preliminary control signals FXB0_PRE, FXB1_PRE, and MWLT_PRE, for example, a third preliminary control signal FXB1_PRE.

The second inverter 114 may output a signal, which is obtained by inverting the third preliminary control signal FXB1_PRE, as still another one of the preliminary control signals FXB0_PRE, FXB1_PRE, and MWLT_PRE, for example, a second preliminary control signal MWLT_PRE.

The second signal generation section 120 may generate a plurality of word line control signals FXB0<0:1>, FXB1<0:1>, and MWLT<0:1> according to the address signal ADD and the preliminary control signals FXB0_PRE, FXB1_PRE, and MWLT_PRE.

The second signal generation section 120 may decode the address signal ADD to generate address decoding signals, and generate signals, which are obtained by combining the address decoding signals and the preliminary control signals FXB0_PRE, FXB1_PRE, and MWLT_PRE, as the plurality of word line control signals FXB0<0:1>, FXB1<0:1>, and MWLT<0:1>.

The second signal generation section 120 may include first to fourth inverters 121 to 124 and first to sixth AND gates 131 to 136.

The first to fourth inverters 121 to 124 may decode address signals ADD<0> and ADD<3> to generate address decoding signals ADDB<0>, ADDT<0>, ADDB<3>, and ADDT<3>.

The first inverter 121 may output a signal, which is obtained by inverting the address signal ADD<0>, as ADDB<0>.

The second inverter 122 may output a signal, which is obtained by inverting ADDB<0>, as ADDT<0>.

The third inverter 123 may output a signal, which is obtained by inverting the address signal ADD<3>, as ADDB<3>.

The fourth inverter 124 may output a signal, which is obtained by inverting ADDB<3>, as ADDT<3>.

The first AND gate 131 may output a result, which is obtained by performing an AND operation on ADDB<0> and the first preliminary control signal FXB0_PRE, as any of first word line control signals FXB0<0:1>, for example, FXB0<0>.

The second AND gate 132 may output a result, which is obtained by performing an AND operation on ADDT<0> and the first preliminary control signal FXB0_PRE, as the other one of the first word line control signals FXB0<0:1>, for example, FXB0<1>.

The third AND gate 133 may output a result, which is obtained by performing an AND operation on ADDB<0> and the third preliminary control signal FXB1_PRE, as any of third word line control signals FXB1<0:1>, for example, FXB1<0>.

The fourth AND gate 134 may output a result, which is obtained by performing an AND operation on ADDT<0> and the third preliminary control signal FXB1_PRE, as the other one of the third word line control signals FXB1<0:1>, for example, FXB1<1>.

The fifth AND gate 135 may output a result, which is obtained by performing an AND operation on ADDB<3> and the second preliminary control signal MWLT_PRE, as any of second word line control signals MWLT<0:1>, for example, MWLT<0>.

The sixth AND gate 136 may output a result, which is obtained by performing an AND operation on ADDT<3> and the second preliminary control signal MWLT_PRE, as the other one of the second word line control signals MWLT<0:1>, for example, MWLT<1>.

The control signal generation unit 101 may allow the first word line control signal FXB0<i> to transition to a high level when the active signal RACT is deactivated for example, when the active signal RACT transitions to a low level.

Hereinafter, the first word line control signal FXB0<i> may be a signal corresponding to the address signal ADD between the first word line control signals FXB0<0:1>.

After the first word line control signal FXB0<i> transitions to a high level and a set delay time, that is, a delay time set in the delay 111 lapses, the control signal generation unit 101 may allow the third word line control signal FXB1<i> to transition to a high level and the second word line control signal MWLT<i> to transition to a low level.

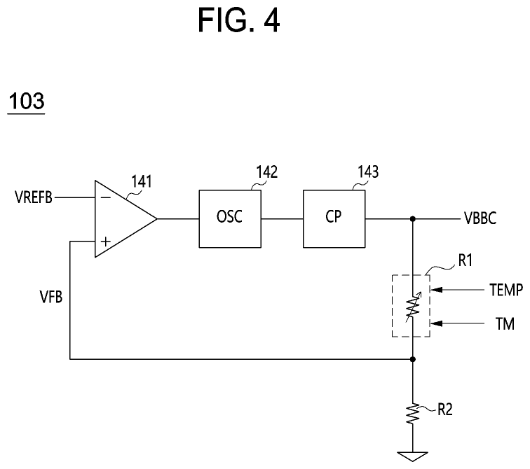

FIG. 4 is a diagram illustrating a configuration of the voltage control unit 103 of FIG. 2, in accordance with an embodiment of the present disclosure. The voltage control unit 103 includes all circuits, systems, software, firmware and devices necessary for its operations and functions.

Referring to FIG. 4, the voltage control unit 103 of FIG. 2 may include a differential amplifier 141, an oscillator 142, a charge pump 143, and distribution resistors R1 and R2.

The differential amplifier 141 may output a result obtained by comparing a reference voltage VREFB and a feedback voltage VFB.

The oscillator 142 may generate an oscillation signal according to the output of the differential amplifier 141.

The charge pump 143 may generate the power supply voltage VBBC by performing a charge pumping operation according to the oscillation signal.

The distribution resistors R1 and R2 may generate the feedback voltage VFB by distributing the power supply voltage VBBC.

Between the distribution resistors R1 and R2, a first resistor R1 may be configured as an active resistor. A resistance value of the first resistor R1 may vary according to the temperature information TEMP and the test mode signal TM.

A second resistor R2 may be configured as a passive resistor.

The temperature information TEMP may be provided by a temperature sensor included in a semiconductor apparatus or an external system that controls the semiconductor apparatus.

The resistance value of the first resistor R1 may be adjusted to a value, which may compensate for a variation of the power supply voltage VBBC due to a temperature change, according to the temperature information TEMP.

The resistance value of the first resistor R1 may be adjusted according to the test mode signal TM regardless of the temperature information TEMP.

As the resistance value of the first resistor R1 is adjusted, the level of the feedback voltage VFB may be adjusted and thus the level of the power supply voltage VBBC may be adjusted.

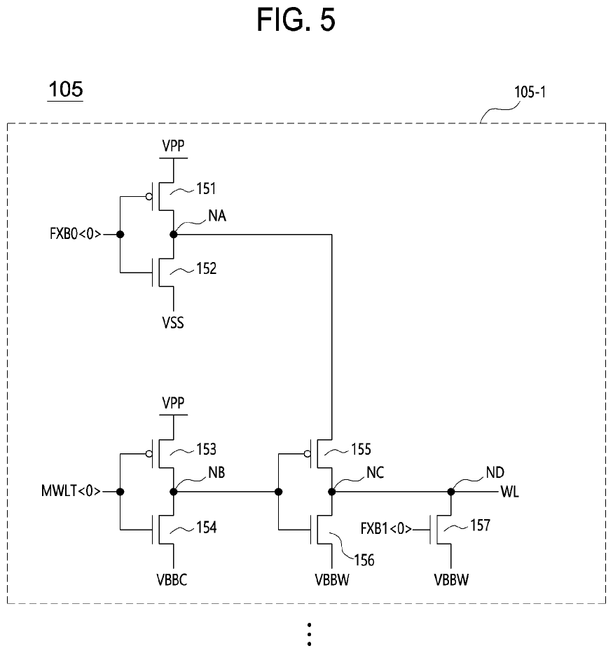

FIG. 5 is a diagram illustrating a configuration of the word line driving unit 105 of FIG. 2, in accordance with an embodiment of the present disclosure.

Referring to FIG. 5, the word line driving unit 105 may include a plurality of word line drivers 105-1. The word line driving unit 105 includes all circuits, systems, software, firmware and devices necessary for its operations and functions.

The plurality of word line drivers 105-1 may be configured identically to one another.

FIG. 5 illustrates a configuration example of the word line driver 105-1 that receives the first word line control signal FXB0<0>, the second word line control signal MWLT<0>, and the third word line control signal FXB1<0> among the plurality of word line drivers 105-1.

Hereinafter, among the plurality of power supply voltages VPP, VSS, VBBW, and VBBC, VPP is referred to as a first power supply voltage, VSS is referred to as a second power supply voltage, VBBC is referred to as a third power supply voltage, and VBBW is referred to as a fourth power supply voltage.

The voltage level of the first power supply voltage VPP may be the highest, the second power supply voltage VSS may be a ground voltage, and the fourth power supply voltage VBBW may have a negative voltage level. The voltage level of the third power supply voltage VBBC may be adjusted as described with reference to FIG. 4 and it is possible to make the third power supply voltage VBBC have a level different from (e.g. lower than) the first power supply voltage VPP. For example, it is also possible to make the third power supply voltage VBBC have a level different from (e.g. lower than) the fourth power supply voltage VBBW.

The word line driver 105-1 may include a first driving unit 151 and 152, a second driving unit 153 to 156, and a third driving unit 157. The first driving unit 151 and 152, the second driving unit 153 to 156, and the third driving unit 157 include all circuits, systems, software, firmware and devices necessary for their respective operations and functions.

The first driving unit 151 and 152 may apply the first power supply voltage VPP or the second power supply voltage VSS to the word line WL according to the first word line control signal FXB0<0>.

The second driving unit 153 to 156 may drop the voltage level of the word line WL to the first target level during the first period by using the third power supply voltage VBBC according to the output of the first driving unit 151 and 152 and the second word line control signal MWLT<0>.

According to the third word line control signal FXB1<0>, the third driving unit 157 may maintain the voltage level of the word line WL substantially at the first target level during the second period and then drop the voltage level of the word line WL to the second target level during the third period by using the fourth power supply voltage VBBW.

The first driving unit 151 and 152, the second driving unit 153 to 156, and the third driving unit 157 may be configured as first to seventh transistors 151 to 157, respectively.

The first transistor 151 may receive the first power supply voltage VPP through a source terminal thereof, receive the first word line control signal FXB0<0> through a gate terminal thereof, and a drain terminal thereof may be electrically connected to a first node NA.

The second transistor 152 may receive the second power supply voltage VSS through a source terminal thereof, receive the first word line control signal FXB0<0> through a gate terminal thereof, and a drain terminal thereof may be electrically connected to the first node NA.

The third transistor 153 may receive the first power supply voltage VPP through a source terminal thereof, receive the second word line control signal MWLT<0> through a gate terminal thereof, and a drain terminal thereof may be electrically connected to a second node NB.

The fourth transistor 154 may receive the third power supply voltage VBBC through a source terminal thereof, receive the second word line control signal MWLT<0> through a gate terminal thereof, and a drain terminal thereof may be electrically connected to the second node NB.

The fifth transistor 155 may have a source terminal electrically connected to the first node NA, a gate terminal electrically connected to the second node NB, and a drain terminal electrically connected to a third node NC.

The sixth transistor 156 may receive the fourth power supply voltage VBBW through a source terminal thereof, a gate terminal thereof may be electrically connected to the second node NB, and a drain terminal thereof may be electrically connected to the third node NC.

The seventh transistor 157 may receive the fourth power supply voltage VBBW through a source terminal thereof, receive the third word line control signal FXB1<0> through a gate terminal thereof, and a drain terminal thereof may be electrically connected to a fourth node ND between the third node NC and the word line WL.

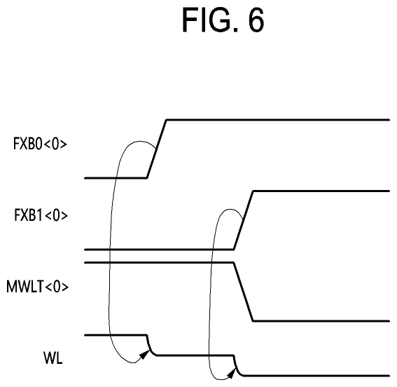

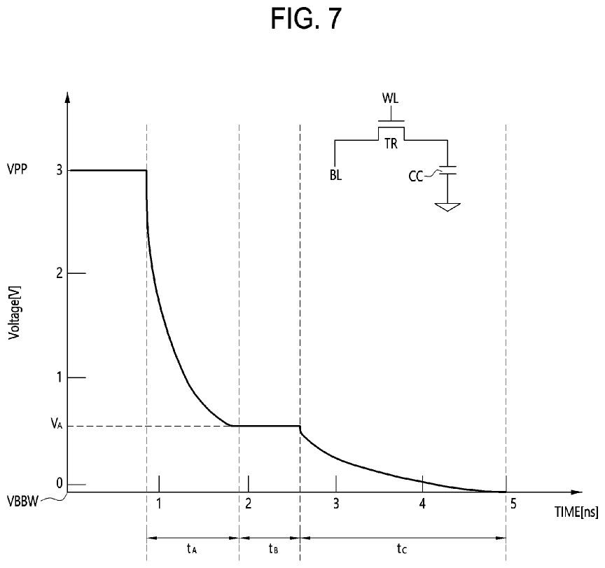

FIG. 6 is a diagram illustrating an operation timing of the word line driving unit 105 of FIG. 5, and FIG. 7 is a diagram illustrating a word line control method in accordance with an embodiment of the present disclosure.

The word line control method in accordance with an embodiment will be described with reference to FIG. 5 to FIG. 7.

As the active signal RACT has a high level according to the active command, the first word line control signal FXB0<0> and the third word line control signal FXB1<0> may have low levels and the second word line control signal MWLT<0> may have a high level.

Since the first word line control signal FXB0<0> and the third word line control signal FXB1<0> are at a low level and the second word line control signal MWLT<0> is at a high level, a current flows through the first transistor 151 and the fifth transistor 155 from the first power supply voltage VPP terminal, so that the voltage level of the word line WL rises to the level of the first power supply voltage VPP.

For example, as the active signal RACT has a low level by the precharge command and the like, the first word line control signal FXB0<0> transitions to a high level.

Since the first word line control signal FXB0<0> transitions to a high level, the third word line control signal FXB1<0> is at a low level, and the second word line control signal MWLT<0> is at a high level, a current flows through the second transistor 152 from the fifth transistor 155, so that the voltage level of the word line WL drops to a first target level V_{A} during a first period t_{A}.

When the level of the third power supply voltage VBBC is a VSS level, that is, 0 V, the first target level V_{A} may be substantially the same as a threshold voltage VT of the fifth transistor 155.

When the level of the third power supply voltage VBBC is less than 0 V, the first target level V_{A} may be lower than the threshold voltage VT of the fifth transistor 155.

During a second period t_{B} for which the first word line control signal FXB0<0> maintains a high level, the third word line control signal FXB1<0> maintains a low level, and the second word line control signal MWLT<0> maintains a high level, the voltage level of the word line WL may be maintained substantially at the first target level V_{A}.

After the first word line control signal FXB0<0> transitions to a high level and the delay time set in the delay 111 of FIG. 3 lapses, the third word line control signal FXB1<0> transitions to a high level and the second word line control signal MWLT<0> transitions to a low level.

Since the first word line control signal FXB0<0> is at a high level, the third word line control signal FXB1<0> is at a high level, and the second word line control signal MWLT<0> is at a low level, a current flows through each of the sixth transistor 156 and the seventh transistor 157, so that the voltage level of the word line WL drops to a second target level during a third period t_{C}, that is, the level of the fourth power supply voltage VBBW.

As described above, as the time required for the voltage level of the word line WL to be maintained at VPP higher than the threshold voltage of the transistor TR becomes longer, the tRP characteristics deteriorate.

In the embodiment described above, by shortening the first period t_{A} for which the voltage level of the word line WL is maintained to be higher than the threshold voltage of the transistor TR for selecting a memory cell, it is possible to substantially prevent deterioration in the tRP characteristics.

Furthermore, the sum of the second period t_{B}, for which the voltage level of the word line WL is maintained substantially at the first target level V_{A}, and the third period t_{C}, for which the voltage level of the word line WL drops to the level of the fourth power supply voltage VBBW, is made longer than the first period t_{A}, so that it is possible to substantially prevent deterioration in the row hammer characteristics.

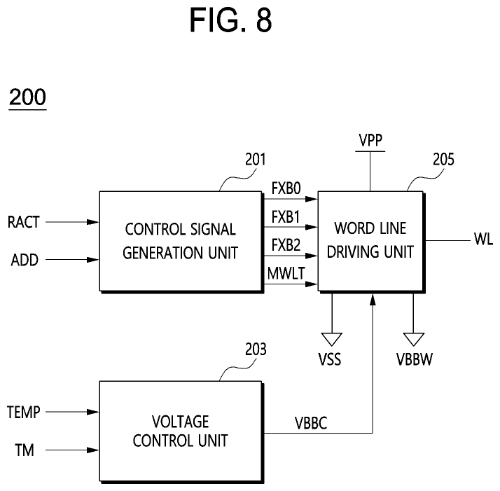

FIG. 8 is a diagram illustrating a configuration of a word line control circuit 200 in accordance with another embodiment of the present disclosure.

Referring to FIG. 8, the word line control circuit 200 in accordance with another embodiment may include a control signal generation unit 201, a voltage control unit 203, and a word line driving unit 205. The control signal generation unit 201, the voltage control unit 203 and the word line driving unit 205 include all circuits, systems, software, firmware and devices necessary for their respective operations and functions.

The control signal generation unit 201 may generate a plurality of word line control signals FXB0, FXB1, FXB2, and MWLT according to an active signal RACT and an address signal ADD.

The active signal RACT is a signal for activating a word line WL, that is, applying a power supply voltage VPP to the word line WL.

As the active signal RACT is activated, that is, as the active signal RACT has a high level, the power supply voltage VPP may be applied to the word line WL.

The active signal RACT may have a high level according to an active command and have a low level according to a precharge command.

The address signal ADD may include a plurality of signal bits, and each of the plurality of word line control signals FXB0, FXB1, FXB2, and MWLT may include a plurality of signal bits.

The word line driving unit 205 may cause a voltage level variation (for example, voltage drop) of the word line WL to be performed in a plurality of steps according to the plurality of word line control signals FXB0, FXB1, FXB2, and MWLT and a plurality of power supply voltages VPP, VSS, VBBW, and VBBC.

The word line driving unit 205 may drop the voltage level of the word line WL to a first target level during a first period, maintain the voltage level of the word line WL substantially at the first target level during a second period, and then drop the voltage level of the word line WL to a second target level during a third period according to the plurality of word line control signals FXB0, FXB1, FXB2, and MWLT and the plurality of power supply voltages VPP, VSS, VBBW, and VBBC.

The voltage control unit 203 may control the first target level according to at least one of temperature information TEMP and a test mode signal TM.

The voltage control unit 203 may generate one power supply voltage VBBC for controlling the first target level among the plurality of power supply voltages VPP, VSS, VBBW, and VBBC according to the temperature information TEMP and the test mode signal TM.

The voltage control unit 203 may adjust the voltage level of VBBC according to the temperature information TEMP and the test mode signal TM.

The voltage control unit 203 may be configured in substantially the same manner as in FIG. 4.

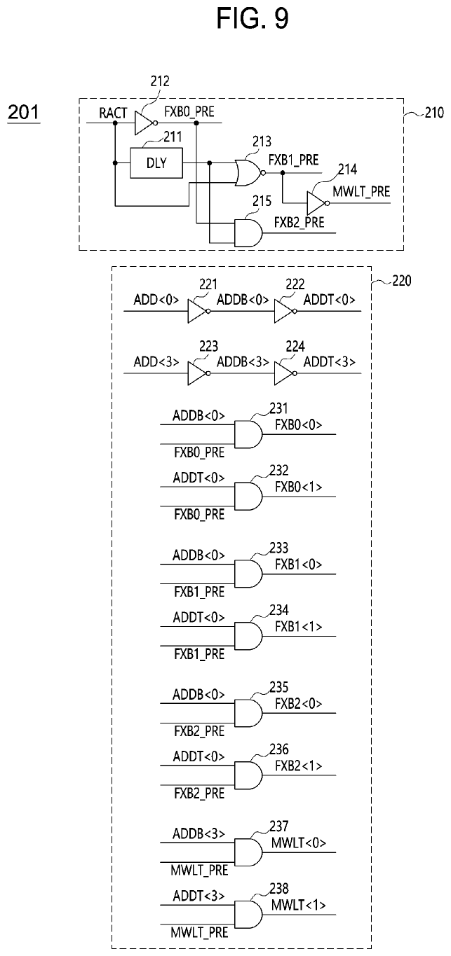

FIG. 9 is a diagram illustrating a configuration of the control signal generation unit 201 of FIG. 8, in accordance with an embodiment of the present disclosure.

FIG. 9 is only an example according to some bits of the address signal ADD, for example, bits in the order of ‘0’ and ‘3’, and the control signal generation unit 201 may have other signal configurations according to the number of bits of the address signal ADD.

Referring to FIG. 9, the control signal generation unit 201 may include a first signal generation section 210 and a second signal generation section 220. The control signal generation unit 201, the first signal generation section 210 and the second signal generation section 220 include all circuits, systems, software, firmware and devices necessary for their respective operations and functions.

The first signal generation section 210 may generate preliminary control signals FXB0_PRE, FXB1_PRE, FXB2_PRE, and MWLT_PRE according to the active signal RACT.

The active signal RACT may have a high level according to the active command and have a low level according to the precharge command.

The first signal generation section 210 may include a delay 211, a first inverter 212, a NOR gate 213, a second inverter 214, and an AND gate 215.

The delay 211 may delay the active signal RACT by a preset time and output the delayed signal.

The first inverter 212 may output a signal, which is obtained by inverting the active signal RACT, as one of the preliminary control signals FXB0_PRE, FXB1_PRE, FXB2_PRE, and MWLT_PRE, for example, a first preliminary control signal FXB0_PRE.

The NOR gate 213 may output a result, which is obtained by performing a NOR operation on the output of the delay 211 and the active signal RACT, as another one of the preliminary control signals FXB0_PRE, FXB1_PRE, FXB2_PRE, and MWLT_PRE, for example, a third preliminary control signal FXB1_PRE.

The second inverter 214 may output a signal, which is obtained by inverting the third preliminary control signal FXB1_PRE, as still another one of the preliminary control signals FXB0_PRE, FXB1_PRE, FXB2_PRE, and MWLT_PRE, for example, a second preliminary control signal MWLT_PRE.

The AND gate 215 may output a signal, which is obtained by performing an AND operation on the first preliminary control signal FXB0_PRE and the output of the delay 211, as yet another one of the preliminary control signals FXB0_PRE, FXB1_PRE, FXB2_PRE, and MWLT_PRE, for example, a fourth preliminary control signal FXB2_PRE.

The second signal generation section 220 may generate a plurality of word line control signals FXB0<0:1>, FXB1<0:1>, FXB2<0:1>, and MWLT<0:1> according to the address signal ADD and the preliminary control signals FXB0_PRE, FXB1_PRE, FXB2_PRE, and MWLT_PRE.

The second signal generation section 220 may decode the address signal ADD to generate address decoding signals, and generate signals, which are obtained by combining the address decoding signals and the preliminary control signals FXB0_PRE, FXB1_PRE, FXB2_PRE, and MWLT_PRE, as the plurality of word line control signals FXB0<0:1>, FXB1<0:1>, FXB2<0:1>, and MWLT<0:1>.

The second signal generation section 220 may include first to fourth inverters 221 to 224 and first to eighth AND gates 231 to 238.

The first to fourth inverters 221 to 224 may decode address signals ADD<0> and ADD<3> to generate address decoding signals ADDB<0>, ADDT<0>, ADDB<3>, and ADDT<3>.

The first inverter 221 may output a signal, which is obtained by inverting the address signal ADD<0>, as ADDB<0>.

The second inverter 222 may output a signal, which is obtained by inverting ADDB<0>, as ADDT<0>.

The third inverter 223 may output a signal, which is obtained by inverting the address signal ADD<3>, as ADDB<3>.

The fourth inverter 224 may output a signal, which is obtained by inverting ADDB<3>, as ADDT<3>.

The first AND gate 231 may output a result, which is obtained by performing an AND operation on ADDB<0> and the first preliminary control signal FXB0_PRE, as any of the first word line control signals FXB0<0:1>, for example, FXB0<0>.

The second AND gate 232 may output a result, which is obtained by performing an AND operation on ADDT<0> and the first preliminary control signal FXB0_PRE, as the other one of the first word line control signals FXB0<0:1>, for example, FXB0<1>.

The third AND gate 233 may output a result, which is obtained by performing an AND operation on ADDB<0> and the third preliminary control signal FXB1_PRE, as any of the third word line control signals FXB1<0:1>, for example, FXB1<0>.

The fourth AND gate 234 may output a result, which is obtained by performing an AND operation on ADDT<0> and the third preliminary control signal FXB1_PRE, as the other one of the third word line control signals FXB1<0:1>, for example, FXB1<1>.

The fifth AND gate 235 may output a result, which is obtained by performing an AND operation on ADDB<0> and the fourth preliminary control signal FXB2_PRE, as any of the fourth word line control signals FXB2<0:1>, for example, FXB2<0>.

The sixth AND gate 236 may output a result, which is obtained by performing an AND operation on ADDT<0> and the fourth preliminary control signal FXB2_PRE, as the other one of the fourth word line control signals FXB2<0:1>, for example, FXB2<1>.

The seventh AND gate 237 may output a result, which is obtained by performing an AND operation on ADDB<3> and the second preliminary control signal MWLT_PRE, as any of the second word line control signals MWLT<0:1>, for example, MWLT<0>.

The eighth AND gate 238 may output a result, which is obtained by performing an AND operation on ADDT<3> and the second preliminary control signal MWLT_PRE, as the other one of the second word line control signals MWLT<0:1>, for example, MWLT<1>.

The control signal generation unit 201 may allow the first word line control signal FXB0<i> to transition to a high level when the active signal RACT is deactivated for example, when the active signal RACT transitions to a low level.

Hereinafter, first word line control signal FXB0<i> may be a signal corresponding to the address signal ADD between the first word line control signals FXB0<0:1>.

After the first word line control signal FXB0<i> transitions to a high level and a set delay time, that is, a delay time set in the delay 211 lapses, the control signal generation unit 201 may allow the third word line control signal FXB1<i> to transition to a high level and the second word line control signal MWLT<i> to transition to a low level.

The control signal generation unit 201 may allow the fourth word line control signal FXB2<i> to transition to a high level at the time point at which the first word line control signal FXB0<i> transitions to a high level, and allow the fourth word line control signal FXB2<i> to transition to a low level at the time point at which the third word line control signal FXB1<i> transitions to a high level. That is, the control signal generation unit 201 may cause the fourth word line control signal FXB2<i> to maintain a high level from the high level transition point of the first word line control signal FXB0<i> to from the high level transition point of the third word line control signal FXB1<i>.

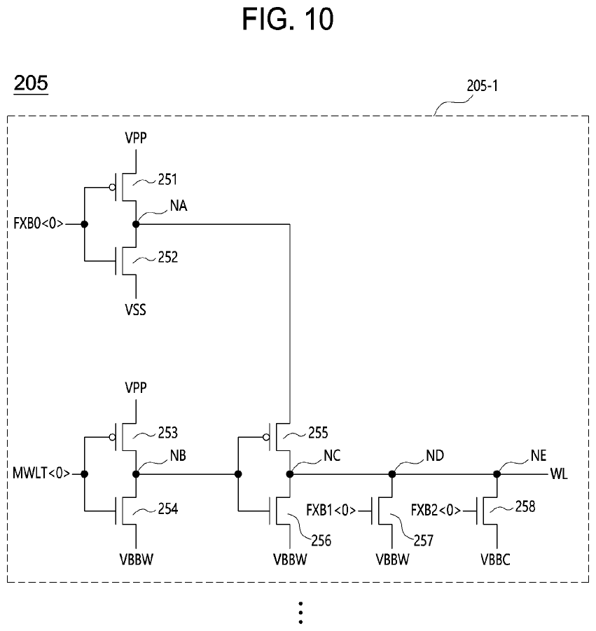

FIG. 10 is a diagram illustrating a configuration of the word line driving unit 205 of FIG. 8, in accordance with an embodiment of the present disclosure. The word line driving unit 205 includes all circuits, systems, software, firmware and devices necessary for its operations and functions.

Referring to FIG. 10, the word line driving unit 205 may include a plurality of word line drivers 205-1.

The plurality of word line drivers 205-1 may be configured identically to one another.

FIG. 10 illustrates a configuration example of the word line driver 205-1 that receives the first word line control signal FXB0<0>, the second word line control signal MWLT<0>, the third word line control signal FXB1<0>, and the fourth word line control signal FXB2<0> among the plurality of word line drivers 205-1.

Hereinafter, among the plurality of power supply voltages VPP, VSS, VBBW, and VBBC, VPP is referred to as a first power supply voltage, VSS is referred to as a second power supply voltage, VBBC is referred to as a third power supply voltage, and VBBW is referred to as a fourth power supply voltage.

The voltage level of the first power supply voltage VPP may be the highest, the second power supply voltage VSS may be a ground voltage, and the fourth power supply voltage VBBW may have a negative voltage level. The voltage level of the third power supply voltage VBBC may be adjusted as described with reference to FIG. 8 and it is possible to make the third power supply voltage VBBC have a level different from (e.g. lower than) the first power supply voltage VPP. For example, it is also possible to make the third power supply voltage VBBC have a level different from (e.g. lower than) the fourth power supply voltage VBBW.

The word line driver 205-1 may include a first driving unit 251 and 252, a second driving unit 258, and a third driving unit 253 to 256, and a fourth driving unit 257. The first driving unit 251 and 252, the second driving unit 258, the third driving unit 253 to 256, and the fourth driving unit 257 include all circuits, systems, software, firmware and devices necessary for their respective operations and functions.

The first driving unit 251 and 252 may apply the first power supply voltage VPP or the second power supply voltage VSS to the word line WL according to the first word line control signal FXB0<0>.

The second driving unit 258 may drop the voltage level of the word line WL to the first target level during the first period and maintain the voltage level of the word line WL substantially at the first target level during the second period by using the third power supply voltage VBBC according to the fourth word line control signal FXB2<0>.

The third driving unit 253 to 256 may drop the voltage level of the word line WL from the first target level to the second target level by using the fourth power supply voltage VBBW according to the output of the first driving unit 251 and 252 and the second word line control signal MWLT<0>.

According to the third word line control signal FXB1<0>, the fourth driving unit 257 may maintain the voltage level of the word line WL substantially at the first target level during the second period and then drop the voltage level of the word line WL to the second target level during the third period by using the fourth power supply voltage VBBW.

The first driving unit 251 and 252, the second driving unit 258, and the third driving unit 253 to 256, and the fourth driving unit 257 may be configured as first to eighth transistors 251 to 258, respectively.

The first transistor 251 may receive the first power supply voltage VPP through a source terminal thereof, receive the first word line control signal FXB0<0> through a gate terminal thereof, and a drain terminal thereof may be electrically connected to a first node NA.

The second transistor 252 may receive the second power supply voltage VSS through a source terminal thereof, receive the first word line control signal FXB0<0> through a gate terminal thereof, and a drain terminal thereof may be electrically connected to the first node NA.

The third transistor 253 may receive the first power supply voltage VPP through the source terminal thereof, receive the second word line control signal MWLT<0> through the gate terminal thereof, and a drain terminal thereof may be electrically connected to a second node NB.

The fourth transistor 254 may receive the fourth power supply voltage VBBW through a source terminal thereof, receive the second word line control signal MWLT<0> through a gate terminal thereof, and a drain terminal thereof may be electrically connected to the second node NB.

The fifth transistor 255 may have a source terminal electrically connected to the first node NA, a gate terminal electrically connected to the second node NB, and a drain terminal electrically connected to a third node NC.

The sixth transistor 256 may receive the fourth power supply voltage VBBW through a source terminal thereof, a gate terminal thereof may be electrically connected to the second node NB, and a drain terminal thereof may be electrically connected to the third node NC.

The seventh transistor 257 may receive the fourth power supply voltage VBBW through a source terminal thereof, receive the third word line control signal FXB1<0> through a gate terminal thereof, and a drain terminal thereof may be electrically connected to a fourth node ND between the third node NC and a fifth node NE.

The eighth transistor 258 may receive the third power supply voltage VBBC through a source terminal thereof, receive the fourth word line control signal FXB2<0> through a gate terminal thereof, and a drain terminal thereof may be electrically connected to the fifth node NE between the fourth node ND and the word line WL.

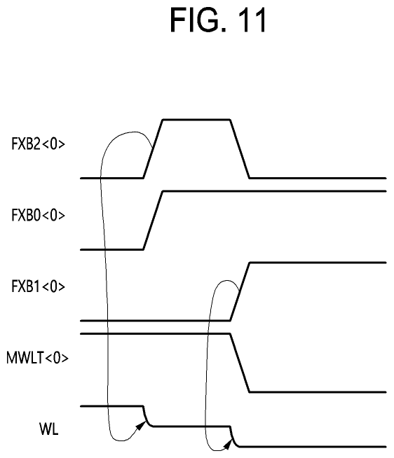

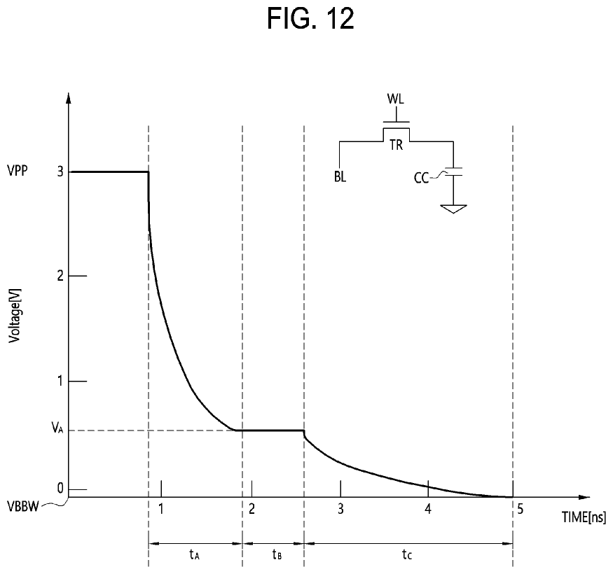

FIG. 11 is a diagram illustrating an operation timing of the word line driving unit 205 of FIG. 10, and FIG. 12 is a diagram illustrating a word line control method in accordance with another embodiment of the present disclosure.

The word line control method in accordance with another embodiment will be described with reference to FIG. 10 to FIG. 12.

As the active signal RACT has a high level according to the active command, the first word line control signal FXB0<0>, the third word line control signal FXB1<0>, and the fourth word line control signal FXB2<0> may have low levels and the second word line control signal MWLT<0> may have a high level.

Since the first word line control signal FXB0<0>, the third word line control signal FXB1<0>, and the fourth word line control signal FXB2<0> are at a low level and the second word line control signal MWLT<0> is at a high level, a current flows through the first transistor 251 and the fifth transistor 255 from the first power supply voltage VPP terminal, so that the voltage level of the word line WL rises to the level of the first power supply voltage VPP.

For example, as the active signal RACT has a low level by the precharge command and the like, the first word line control signal FXB0<0> and the fourth word line control signal FXB2<0> transition to high levels.

Since the first word line control signal FXB0<0> and the fourth word line control signal FXB2<0> transition to high levels, the third word line control signal FXB1<0> is at a low level, and the second word line control signal MWLT<0> is at a high level, a current flows through the second transistor 252 from the fifth transistor 255 and a current flows through the eighth transistor 258, so that the voltage level of the word line WL drops to a first target level V_{A} during a first period t_{A}.

The first target level V_{A} may be substantially the same as the level of the third power supply voltage VBBC.

During a second period t_{B} for which the first word line control signal FXB0<0> and the fourth word line control signal FXB2<0> maintain high levels, the third word line control signal FXB1<0> maintains a low level, and the second word line control signal MWLT<0> maintains a high level, the voltage level of the word line WL may be maintained substantially at the first target level V_{A}.

After the first word line control signal FXB0<0> transitions to a high level and the delay time set in the delay 211 of FIG. 9 lapses, the third word line control signal FXB1<0> transitions to a high level and the second word line control signal MWLT<0> and the fourth word line control signal FXB2<0> transition to low levels.

Since the first word line control signal FXB0<0> and the third word line control signal FXB1<0> are at a high level and the second word line control signal MWLT<0> and the fourth word line control signal FXB2<0> are at a low level, a current flows through each of the sixth transistor 256 and the seventh transistor 257, so that the voltage level of the word line WL drops to a second target level during a third period t_{C}, that is, the level of the fourth power supply voltage VBBW.

In another embodiment described above, by shortening the first period t_{A} for which the voltage level of the word line WL is maintained to be higher than the threshold voltage of the transistor TR for selecting a memory cell, it is possible to substantially prevent deterioration in the tRP characteristics.

Furthermore, the sum of the second period t_{B}, for which the voltage level of the word line WL is maintained substantially at the first target level V_{A}, and the third period t_{C}, for which the voltage level of the word line WL drops to the level of the fourth power supply voltage VBBW, is made longer than the first period t_{A}, so that it is possible to substantially prevent deterioration in the row hammer characteristics.

Furthermore, by adding the eighth transistor 258 that controls a direct current path from the third power supply voltage VBBC terminal of FIG. 10 to the word line WL, it is possible to more efficiently control the first period t_{A} and the second period t_{B}.

Moreover, the embodiments of the present disclosure have been described in the drawings and specification. Although specific terminologies are used here, those are only to describe the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein. The embodiments may be combined to form additional embodiments.

A person skilled in the art to which the present disclosure pertains can understand that the present disclosure may be carried out in other specific forms without changing its technical spirit or essential features. Therefore, it should be understood that the embodiments described above are illustrative in all respects, not limitative. The scope of the present disclosure is defined by the claims to be described below rather than the detailed description, and it should be construed that the meaning and scope of the claims and all modifications or modified forms derived from the equivalent concept thereof are included in the scope of the present disclosure.

What is claimed is:

1. A word line control circuit comprising:
a first driving unit configured to apply a first power supply voltage or a second power supply voltage to a word line according to a first word line control signal;
a second driving unit configured to drop a voltage level of the word line to a first target level during a first period by using a third power supply voltage according to an output of the first driving unit and a second word line control signal; and
a third driving unit configured to maintain the voltage level of the word line substantially at the first target level during a second period and to drop the voltage level of the word line to a second target level during a third period by using a fourth power supply voltage, according to a third word line control signal.

2. The word line control circuit according to claim 1, wherein the fourth power supply voltage has a negative voltage level lower than the second power supply voltage and the third power supply voltage has a lower level than the first power supply voltage.

3. The word line control circuit according to claim 1, wherein the first target level is adjusted by varying a level of the third power supply voltage.

4. The word line control circuit according to claim 1, wherein a level of the third power supply voltage is adjusted according to at least one of temperature information and a test mode signal of a semiconductor apparatus including the word line control circuit.

5. A semiconductor apparatus comprising:
a control signal generation unit configured to generate a plurality of word line control signals in response to an active signal; and
a word line driving unit configured to drop a voltage level of a word line to a first target level during a first period, to maintain the voltage level of the word line substantially at the first target level during a second period, and to drop the voltage level of the word line to a second target level during a third period, according to the plurality of word line control signals.

6. The semiconductor apparatus according to claim 5, further comprising a voltage control unit configured to control the first target level according to at least one of temperature information and a test mode signal of the semiconductor apparatus.

7. The semiconductor apparatus according to claim 5, wherein the control signal generation unit comprises:
a first signal generation section configured to generate preliminary control signals according to the active signal; and
a second signal generation section configured to decode an address signal to generate address decoding signals, and to generate signals, which are obtained by combining the address decoding signals and the preliminary control signals, as the plurality of word line control signals.

8. The semiconductor apparatus according to claim 5, wherein the word line driving unit comprises:
a first transistor configured to apply a first power supply voltage to a first node according to a first word line control signal among the plurality of word line control signals;
a second transistor configured to apply a second power supply voltage to the first node according to the first word line control signal;
a third transistor configured to apply the first power supply voltage to a second node according to a second word line control signal among the plurality of word line control signals;
a fourth transistor configured to apply a third power supply voltage to the second node according to the second word line control signal;
a fifth transistor configured to apply a voltage level of the first node to a third node according to a voltage level of the second node;
a sixth transistor configured to apply a fourth power supply voltage to the third node according to the voltage level of the second node; and
a seventh transistor electrically connected to a fourth node between the third node and the word line and configured to apply the fourth power supply voltage to the fourth node according to a third word line control signal among the plurality of word line control signals.

9. The semiconductor apparatus according to claim 8, wherein the first word line control signal transitions from a first logic level to a second logic level in response to deactivation of the active signal, the second word line control signal transitions from the second logic level to the first logic level after the first word line control signal transitions to the second logic level and the second period lapses, and the third word line control signal transitions from the first logic level to the second logic level after the first word line control signal transitions to the second logic level and the second period lapses.

10. The semiconductor apparatus according to claim 5, wherein the word line driving unit comprises:
a first driving unit configured to apply a first power supply voltage or a second power supply voltage to the word line according to a first word line control signal among the plurality of word line control signals;
a second driving unit configured to drop the voltage level of the word line to the first target level during the first period by using a third power supply voltage according to a fourth word line control signal among the plurality of word line control signals;
a third driving unit configured to drop the voltage level of the word line from the first target level to the second target level by using a fourth power supply voltage according to an output of the first driving unit and a second word line control signal among the plurality of word line control signals; and
a fourth driving unit configured to maintain the voltage level of the word line substantially at the first target level during the second period and to drop the voltage level of the word line to the second target level during the third period by using the fourth power supply voltage, according to a third word line control signal among the plurality of word line control signals.

11. The semiconductor apparatus according to claim 10, wherein the fourth power supply voltage has a negative voltage level lower than the second power supply voltage, and the third power supply voltage has a lower level than the first power supply voltage.

12. The semiconductor apparatus according to claim 10, wherein the first target level is adjusted by varying a level of the third power supply voltage.

13. A semiconductor apparatus configured to drop a voltage level of a word line to a first target level during a first period in response to an active signal, to maintain the voltage level of the word line substantially at the first target level during a second period, and to drop the voltage level of the word line to a second target level during a third period.

14. The semiconductor apparatus according to claim 13, wherein the semiconductor apparatus comprises:
a control signal generation unit configured to generate a plurality of word line control signals in response to the active signal; and
a word line driving unit configured to drop the voltage level of the word line to the first target level during the first period, to maintain the voltage level of the word line substantially at the first target level during the second period, and to drop the voltage level of the word line to the second target level during the third period, according to the plurality of word line control signals.

15. The semiconductor apparatus according to claim 14, further comprising a voltage control unit configured to control the first target level according to at least one of temperature information and a test mode signal of the semiconductor apparatus.

16. The semiconductor apparatus according to claim 14, wherein the control signal generation unit comprises:
a first signal generation section configured to generate preliminary control signals according to the active signal; and
a second signal generation section configured to decode an address signal to generate address decoding signals, and to generate signals, which are obtained by combining the address decoding signals and the preliminary control signals, as the plurality of word line control signals.

17. The semiconductor apparatus according to claim 14, wherein the word line driving unit comprises:
a first transistor configured to apply a first power supply voltage to a first node according to a first word line control signal among the plurality of word line control signals;
a second transistor configured to apply a second power supply voltage to the first node according to the first word line control signal;
a third transistor configured to apply the first power supply voltage to a second node according to a second word line control signal among the plurality of word line control signals;
a fourth transistor configured to apply a third power supply voltage to the second node according to the second word line control signal;
a fifth transistor configured to apply a voltage level of the first node to a third node according to a voltage level of the second node;
a sixth transistor configured to apply a fourth power supply voltage to the third node according to the voltage level of the second node; and
a seventh transistor electrically connected to a fourth node between the third node and the word line and configured to apply the fourth power supply voltage to the fourth node according to a third word line control signal among the plurality of word line control signals.

18. The semiconductor apparatus according to claim 17, wherein the first word line control signal transitions from a first logic level to a second logic level in response to deactivation of the active signal, the second word line control signal transitions from the second logic level to the first logic level after the first word line control signal transitions to the second logic level and the second period lapses, and the third word line control signal transitions from the first logic level to the second logic level after the first word line control signal transitions to the second logic level and the second period lapses.

19. An operating method of a semiconductor apparatus including a memory cell array coupled to word lines, the operating method comprising:
raising, in response to an active command, a voltage level of a selected word line to a power voltage level;
lowering, in response to a precharge command, the voltage level to a threshold voltage level or a lower level of a selecting transistor configured to couple a memory cell to the selected word line during a first period;
keeping the voltage level during a second period; and
lowering the voltage level to a negative level during a third period,
wherein the first period is shorter than a sum of the second and third periods.
